(19) United States
(12) Patent Application Publication
(10) Pub. No.: US 2007/0034948 A1
(43) Pub. Date: Feb. 15, 2007

(54) SILICIDATION PROCESS FOR AN NMOS TRANSISTOR AND CORRESPONDING INTEGRATED CIRCUIT

(75) Inventors: Florian Cacho, Grenoble (FR); Benoit Froment, Bruxelles (BE)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics (Crolles 2) SAS, Crolles (FR)

(21) Appl. No.: 11/458,497

(22) Filed: Jul. 19, 2006

(30) Foreign Application Priority Data
Jul. 20, 2005 (FR) 0507713

(51) Int. Cl. H01L 29/76; H01L 29/94; H01L 31/00

(52) U.S. Cl. 257/344

(57) ABSTRACT

An integrated circuit provided with an NMOS transistor includes a metal silicide on source, drain and gate regions and also on at least one portion of the source and drain extension zones The metal silicide portion located on the source and drain extension zones is thinner than the metal silicide portion located on the source and drain regions.

### FIELD OF THE INVENTION

The invention relates to integrated circuits, and in particular, to the silicidation of NMOS transistors.

### BACKGROUND OF THE INVENTION

Metal silicides, formed by the “self-aligned silicide” process, are located in the source and drain regions and on the gates of CMOS transistors. In the standard process, they are conventionally used to promote metal interconnections, and to also reduce access resistances. Moreover, since there is a continuing trend towards ever shallower junction depths, it is necessary to reduce the silicide thicknesses to avoid leakage currents.

The silicide layer also generates a tensile stress in the conduction channel, and thus modifies the performance characteristics of the transistor, mainly the drain current Iₒₙ when the transistor is on. This tensile stress increases the Iₒₙ in NMOS transistors, but decreases the Iₒₙ in PMOS transistors. Thus, any improvement in one direction for one type of transistor is to the detriment of the other type of transistor.

For a given silicide, the amplitude of the silicide-induced stress depends on the size of the spacers and on the thickness of the silicide layer. The choice of thickness of the silicide layer to be formed is made so as to obtain an acceptable access resistance, while limiting the leakage current in the source and drain regions Thus, when a thin silicide layer is produced in the active zones, the leakage current is low, but the access resistance is high and the stress in the channel is low. When a thick silicide layer is formed in the active zones, the access resistance is low and the stress is high, but the leakage current is high. The production of metal silicide zones therefore needs to take into account several divergent parameters.

In addition, the use of these silicides has another drawback. It is not possible to control the silicide/silicon phase transformation front during the silicidation anneal. This is because it is very difficult to control the diffusion of the metal within the silicon. Such as for example, its diffusion rate, the diffusing species or the location of the silicide. It is possible for the silicide to diffuse beneath the spacer or beneath the gate. It is therefore very difficult to ascertain the precise structure/architecture of the silicide layer formed.

### SUMMARY OF THE INVENTION

In view of the foregoing background, an object of the invention is to reduce the access resistance between the channel outlet and the active zone, to reduce the leakage current and to allow better control of the diffusion of the silicide/silicon transformation front, and to also locally increase the channel stress which is beneficial for NMOS transistors.

This and other objects, advantages and features in accordance with the present invention are provided by an integrated circuit comprising at least one NMOS transistor comprising a metal silicide on the source, drain and gate regions and also on at least one portion of the source extension and drain extension zones. The metal silicide portion located on the source extension and drain extension zones may be thinner than the portion located on the source region and drain region.

The metal silicide may comprise nickel silicide. The thickness of the metal silicide layer lying on the source extension and drain extension zones may be within a range of 5 and 15 nm.

Another aspect of the invention is directed to a process for forming a metal silicide on an NMOS transistor comprising a first silicidation phase on the source, drain and gate regions for producing a first metal silicide, and a second silicidation phase on at least part of the source extension and drain extension zones for producing a second silicide thinner than the first silicide.

The second silicidation phase may comprise the following steps: passivation of the first metal silicide; partial etching of the spacers; deposition of a metal layer thinner than that deposited in order to form the second metal silicide; and then at least one silicidation anneal. The process may include a step of cleaning the portion exposed by the etching before the metal layer is deposited

### BRIEF DESCRIPTION OF THE DRAWINGS

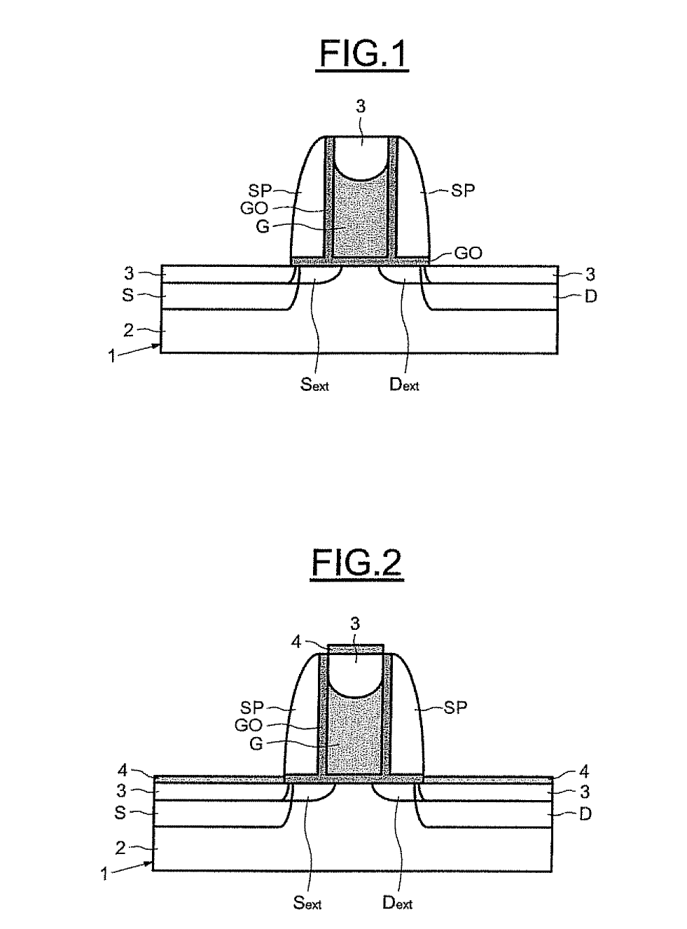

Other advantages and features of the invention will become apparent upon examining the detailed description of a non-limiting mode of implementation, and the appended drawings in which FIGS. 1 to 4 schematically illustrate the main steps of implementing the process resulting in an integrated circuit according to the invention.

### DETAILED DESCRIPTION OF THE PREFERRED EMBODIMENTS

During the simultaneous fabrication of NMOS and PMOS transistors, the PMOS transistors are masked before carrying out the silicidation of the NMOS transistors of an integrated circuit according to the invention.

FIG. 1 shows an NMOS transistor 1 comprising within a silicon substrate 2 a source region S, a source extension zone Sₑₓₜ, a drain region D, a drain extension zone Dₑₓₜ, a polysilicon gate G, a gate oxide GO and spacers SP located on either side of the gate G. The transistor 1 has already undergone a first conventional silicidation phase and has a metal silicide layer 3 on the source S, the gate G and the drain D. Conventionally, the thickness of the silicide layer is between 15 and 25 nm.

The metal silicides are those conventionally used, such as for example, NiSi, TiSi₂, CoSi₂, Ni(Pt)Si, and NiSiGe. Preferably, nickel silicide is used since it makes it possible to obtain a low thermal budget and possesses a lower resistivity than that of CoSi₂, while consuming less silicon.

FIG. 2 shows the transistor 1 obtained following the passivation reaction carried out on the silicide 3, for example by an oxygen-containing plasma. This passivation forms a MetalSiOx oxide 4 over the entire surface of the metal silicide 3 of the transistor 1. That is, on the source S, the gate G and the drain D. By passivating the silicide it is possible to protect the silicide from the subsequent steps of the process, such as the etching or the second silicidation. The passivated metal oxide layer 4 can be easily removed in the continuation of the process, for example by heating or by etching, depending on the nature of the metal. Alternatively, the passivated metal oxide layer 4 may be preserved by etching only the zone needed for producing the contact.

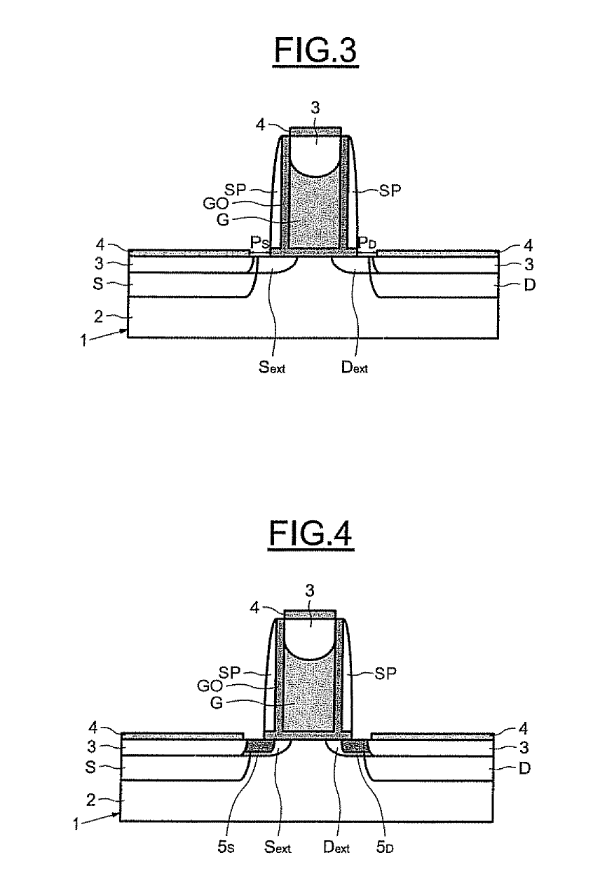

FIG. 3 shows the transistor 1 obtained after the spacers SP have been etched. This is a conventional step, such as for example, wet etching using phosphoric acid or by dry etching using an O₂ plasma. This etching operation exposes the portions P_{S} and P_{D} located on the non-silicided source extension Sₑₓₜ and drain extension Dₑₓₜ zones lying between the passivated layers 4 extending over the source, drain and gate regions The etching-exposed portions P_{S} and P_{D} may be cleaned, for example by a hydrofluoric acid solution conventionally used for this type of cleaning.

A layer of metal with a thickness of less than that deposited during the first silicidation is then deposited on the transistor 1. As a general rule, the thickness of the second layer of metal to be silicided is 50% less than the thickness of the first layer. The transistor 1 illustrated in FIG. 3 then undergoes at least one silicidation anneal, allowing metal silicide formation on the source extension Sₑₓₜ and drain extension Dₑₓₜ zones.

The silicidation operating conditions, for example one-step or two-step silicidation and the temperature and duration of the anneal, may then be adjusted so as to obtain the desired silicide layer thickness. The metal that has not reacted, especially that deposited on the spacers SP of FIG. 4, is then selectively etched.

FIG. 4 illustrates the transistor 1 comprising the silicide portions 5_{S} and 5_{D} formed during the second silicidation anneal. This two-step silicidation process has the advantage of allowing better control of the metal silicide diffusion into the transistor, especially into the zones close to the channel. This is because by depositing a first layer, with a thickness less than that conventionally deposited, and then depositing a second layer of metal of even smaller thickness, it is possible to modulate the final silicide thickness to match the junction depth.

This process also makes it possible to reduce the access resistance between the channel and the active zone and to limit the leakage currents This process also improves the performance characteristics of NMOS transistors, since the mean tensile stress (in the direction of the channel) beneath the gate will increase without affecting the performance characteristics of the PMOS transistors. The performance characteristics are masked during the silicidation carried out on the NMOS transistors.

1-6. (canceled)

7. An integrated circuit comprising:
a silicon substrate; and
at least one NMOS transistor in said substrate and comprising
source and drain regions defining a channel therebetween,
a gate overlying the channel,
source and drain extension zones adjacent the channel and said source and drain regions,
a first metal silicide layer on said source and drain regions, and on said gate,
a second metal silicide layer on said source and drain extension zones, and having a thickness less than a thickness of said first metal silicide layer

8. An integrated circuit according to claim 7, wherein said first and second metal silicide layers each comprises nickel silicide.

9. An integrated circuit according to claim 7, wherein the thickness of said second metal silicide layer is between 5 and 15 nm.

10. An integrated circuit according to claim 7, wherein the thickness of said first metal silicide layer is between 15 and 25 nm.

11. An integrated circuit according to claim 7, wherein the thickness of said second metal silicide layer is less than one-half the thickness of said first metal silicide layer.

12. An integrated circuit comprising:
a silicon substrate; and
at least one PMOS transistor in said semiconductor substrate; and
at least one NMOS transistor in said substrate and comprising
source and drain regions defining a channel therebetween,
a gate overlying the channel,
source and drain extension zones adjacent the channel and said source and drain regions,
a first metal silicide layer on said source and drain regions, and on said gate,
a second metal silicide layer on said source and drain extension zones, a thickness of said second metal silicide layer is less than one-half a thickness of said first metal silicide layer.

13. An integrated circuit according to claim 12, wherein said first and second metal silicide layers each comprises nickel silicide.

14. An integrated circuit according to claim 12, wherein the thickness of said second metal silicide layer is between 5 and 15 nm.

15. An integrated circuit according to claim 12, wherein the thickness of said first metal silicide layer is between 15 and 25 nm.

16. A process for forming a metal silicide on an NMOS transistor comprising a substrate; and at least one NMOS transistor in the substrate and comprising source and drain regions defining a channel therebetween, a gate overlying the channel, and source and drain extension zones adjacent the channel and the source and drain regions, the method comprising:
forming a first metal silicide layer on the source and drain regions, and on the gate; and
forming a second metal silicide layer on the source and drain extension zones, the second metal silicide layer having a thickness less than a thickness of the first metal silicide layer.

17. A process according to claim 16, wherein forming the second metal silicide layer comprises:
passivating the first metal silicide layer;
forming spacers on sidewalls of the gate;
partially etching the spacers to expose portions of the source and drain extension zones;
depositing a metal layer thicker than the first metal silicide layer on the exposed source and drain extension zones; and
performing at least one silicidation anneal.

18. A process according to claim 17, further comprising cleaning the exposed portions of the source and drain extension zones before depositing the metal layer is deposited.

19. A process according to claim 16, wherein the first and second metal silicide layers each comprises nickel silicide.

20. A process according to claim 16, wherein the thickness of the second metal silicide layer is between 5 and 15 nm.

21. A process according to claim 16, wherein the thickness of the first metal silicide layer is between 15 and 25 nm.

22. A process according to claim 16, wherein the thickness of the second metal silicide layer is less than one-half the thickness of the first metal silicide layer.
